(19) United States
(12) Patent Application Publication
(10) Pub. No.: US 2010/0330731 A1
(43) Pub. Date: Dec. 30, 2010

(54) METHOD TO FORM A THIN SEMICONDUCTOR LAMINA ADHERED TO A FLEXIBLE SUBSTRATE

(75) Inventors: Aditya Agarwal, Sunnyvale, CA (US); Kathy J. Jackson, Felton, CA (US)

Correspondence Address: THE MUELLER LAW OFFICE, P.C., 12951 Harwick Lane, San Diego, CA, 92130, US

(73) Assignee: TWIN CREEKS TECHNOLOGIES, INC., San Jose, CA (US)

(21) Appl. No.: 12/493,195

(22) Filed: Jun. 27, 2009

(51) Int. Cl. H01L 31/18; H01L 21/30

(52) U.S. Cl. 438/73; 438/458; 257/E21.211

(57) ABSTRACT

A semiconductor donor body such as a wafer is implanted with ions to form a cleave plane. The donor wafer is affixed to a polyimide receiver element, for example by applying polyimide in liquid form to the donor wafer, then curing, or by affixing the donor wafer to a preformed polyimide sheet. Annealing causes a lamina to cleave from the donor wafer at the cleave plane. The resulting adhered lamina and polyimide body are not adhered to another rigid substrate and can be jointly flexed.

### RELATED APPLICATIONS

This application is related to Agarwal et al., US patent application Ser. No. ______, “Thin Semiconductor Lamina Adhered to a Flexible Substrate,” (attorney docket number TWINP036/TCA-033z), filed on even date herewith, owned by the assignee of the present application, and hereby incorporated by reference.

### BACKGROUND OF THE INVENTION

The invention relates to a method to form a thin semiconductor lamina adhered to a receiver element. A photovoltaic cell, or some other device, may be fabricated from such a structure.

It is known to implant hydrogen ions to a predetermined depth into a silicon wafer, then to adhere the silicon wafer to another rigid body. This rigid body may be, for example, a second wafer, such as an oxide wafer or another silicon wafer having an oxide layer on its adhered surface. Annealing of this structure creates a plane of weakness at the depth of the hydrogen implant. The silicon wafer parts at the plane of weakness, leaving a thin layer of silicon adhered to the second wafer. Devices may be fabricated in the thin silicon layer. Silicon-on-insulator devices may be created in this manner.

Such devices are rigid, and relatively heavy to transport. There is utility, therefore, in developing such a structure with a lightweight, flexible supporting substrate.

### SUMMARY OF THE PREFERRED EMBODIMENTS

The present invention is defined by the following claims, and nothing in this section should be taken as a limitation on those claims. In general, the invention is directed to fabrication of a photovoltaic cell, or other device, comprising a thin semiconductor lamina adhered to a flexible substrate, and methods for forming such a structure.

A first aspect of the invention provides for method to form a plurality of flexible structures, the method comprising: providing a polyimide substrate; affixing a plurality of substantially crystalline semiconductor wafers to the polyimide substrate, each semiconductor wafer having a cleave plane defined within; and cleaving a semiconductor lamina from each wafer of the plurality at the cleave plane, the semiconductor laminae remaining affixed to the polyimide substrate.

Another aspect of the invention provides for a method to form a flexible structure, the method comprising providing a substantially crystalline semiconductor donor body having a cleave plane defined within; providing a cured polyimide receiver affixed to the donor body at a first surface of the donor body, wherein one or more layers have previously been formed on the first surface, and wherein the polyimide is affixed only to the semiconductor donor body and is not affixed to any other substrate; and cleaving a semiconductor lamina from the semiconductor donor body at the cleave plane, the semiconductor lamina remaining affixed to the cured polyimide receiver.

An embodiment of the invention provides for a method to form a plurality of photovoltaic structures, the method comprising: providing a polyimide substrate; affixing a plurality of substantially crystalline semiconductor wafers to the polyimide substrate, each semiconductor wafer having a cleave plane defined within; cleaving a semiconductor lamina from each wafer of the plurality at the cleave plane, the semiconductor laminae remaining affixed to the polyimide substrate; and fabricating a plurality of photovoltaic cells, wherein each photovoltaic cell comprises one of the semiconductor laminae.

Yet another aspect of the invention provides for a method to form a photovoltaic cell, the method comprising: providing a polyimide sheet; affixing a substantially crystalline semiconductor wafer to the polyimide sheet, the semiconductor wafer having a cleave plane defined within; cleaving a semiconductor lamina from the wafer at the cleave plane, the semiconductor lamina remaining affixed to the polyimide sheet, the lamina having a thickness between about two and about six microns; and fabricating a photovoltaic cell, wherein the photovoltaic cell comprises the semiconductor lamina.

Each of the aspects and embodiments of the invention described herein can be used alone or in combination with one another.

The preferred aspects and embodiments will now be described with reference to the attached drawings.

### BRIEF DESCRIPTION OF THE DRAWINGS

FIG. 1 is a cross-sectional drawing of a prior art photovoltaic cell.

FIGS. 2a-2d are cross-sectional drawings of stages of fabrication of a photovoltaic cell formed according to an embodiment of Sivaram et al.

FIGS. 3a and 3b are cross-sectional views illustrating fabrication of a flexible structure including a thin semiconductor lamina and a polyimide receiver element formed by applying polyimide in liquid form and curing.

FIG. 4 is a cross-sectional view illustrating a semiconductor wafer having a cleave plane defined within, the wafer adhered to a polyimide sheet.

FIG. 5 is a cross-sectional view of a structure including a cured polyimide receiver element and a thin semiconductor lamina, where the receiver element and lamina can be jointly flexed. Flexing is shown in each direction.

FIG. 6 is flow chart of a process to form a flexible structure.

FIGS. 7a-7c are cross-sectional views showing stages in formation of a photovoltaic cell formed according to an embodiment of the present invention.

FIGS. 8a and 8b are cross-sectional views showing stages in formation of a photovoltaic cell formed according to another embodiment of the present invention. FIGS. 8c and 8d are embodiments shown in plan view.

FIG. 9 is flow chart of a process to form a plurality of flexible structures.

FIG. 10 is a flow chart of a process to form a plurality of photovoltaic cells.

### DETAILED DESCRIPTION OF THE PREFERRED EMBODIMENTS

A conventional prior art photovoltaic cell includes a p−n diode; an example is shown in FIG. 1. A depletion zone forms at the p−n junction, creating an electric field. Incident photons (incident light is indicated by arrows) knock electrons from the valence band to the conduction band, creating free electron-hole pairs. Within the electric field at the p−n junction, electrons tend to migrate toward the n region of the diode, while holes migrate toward the p region, resulting in current, called photocurrent. Typically the dopant concentration of one region will be higher than that of the other, so the junction is either an n−/p+ junction (as shown in FIG. 1) or a p−/n+ junction. The more lightly doped region is known as the base of the photovoltaic cell, while the more heavily doped region is known as the emitter. Most carriers are generated within the base, and it is typically the thickest portion of the cell. The base and emitter together form the active region of the cell. The cell also frequently includes a heavily doped contact region in electrical contact with the base, and of the same conductivity type, to improve current flow. In the example shown in FIG. 1, the heavily doped contact region is n-type.

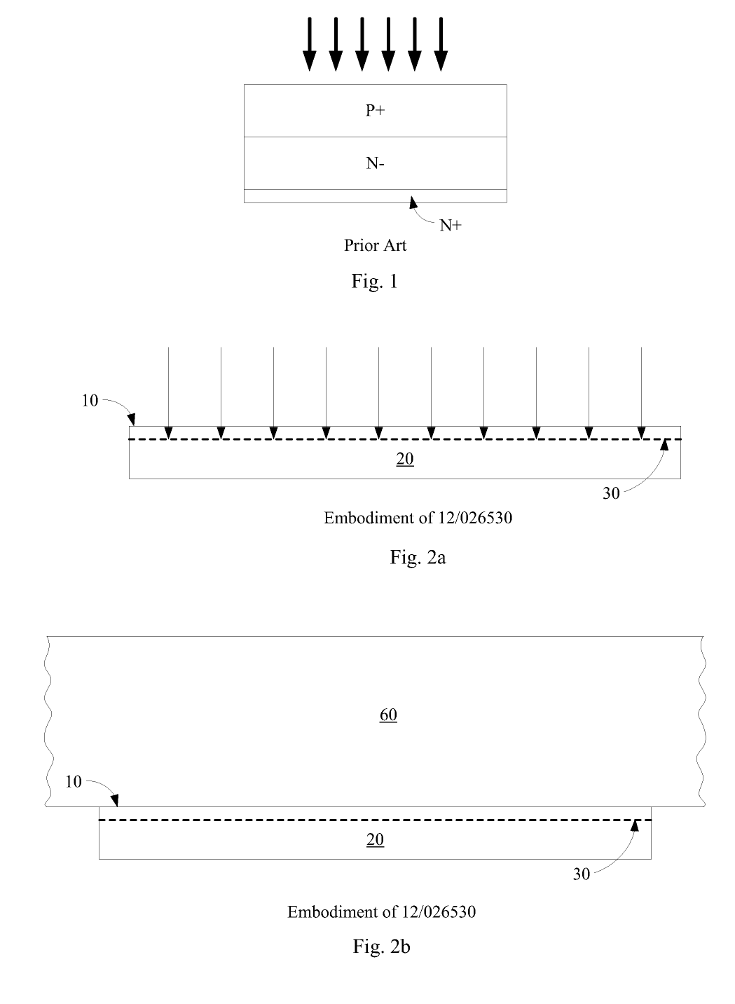

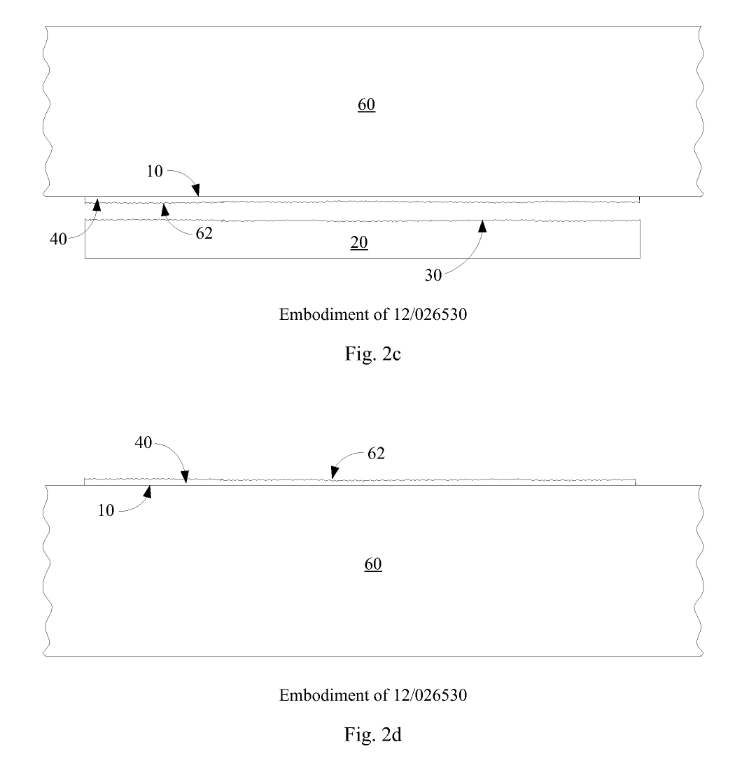

Sivaram et al., U.S. patent application Ser. No. 12/026,530, “Method to Form a Photovoltaic Cell Comprising a Thin Lamina,” filed Feb. 5, 2008, owned by the assignee of the present invention and hereby incorporated by reference, describes fabrication of a photovoltaic cell comprising a thin semiconductor lamina formed of non-deposited semiconductor material. Referring to FIG. 2a, in embodiments of Sivaram et al., a semiconductor donor wafer 20 is implanted with one or more species of gas ions, for example hydrogen ions. Helium ions may optionally be implanted as well. The implanted ions define a cleave plane 30 within the semiconductor donor wafer. As shown in FIG. 2b, donor wafer 20 is affixed at first surface 10 to receiver 60. Referring to FIG. 2c, an anneal causes lamina 40 to cleave from donor wafer 20 at cleave plane 30, creating second surface 62. In embodiments of Sivaram et al., additional processing before and after the cleaving step forms a photovoltaic cell comprising semiconductor lamina 40, which is between about 0.2 and about 100 microns thick, for example between about 0.2 and about 50 microns, for example between about 1 and about 20 microns thick, in some embodiments between about 1 and about 10 microns thick, though any thickness within the named range is possible. FIG. 2d shows the structure inverted, with receiver 60 at the bottom, as during operation in some embodiments. Receiver 60 may be a discrete receiver element having a maximum width no more than 50 percent greater than that of donor wafer 10, and preferably about the same width, as described in Herner, U.S. patent application Ser. No. 12/057,265, “Method to Form a Photovoltaic Cell Comprising a Thin Lamina Bonded to a Discrete Receiver Element,” filed on Mar. 27, 2008, owned by the assignee of the present application and hereby incorporated by reference.

Using the methods of Sivaram et al., rather than being formed from sliced wafers, photovoltaic cells are formed of thin semiconductor laminae without wasting silicon through excessive kerf loss or by fabrication of an unnecessarily thick cell, thus reducing cost. The same donor wafer can be reused to form multiple laminae, further reducing cost.

Sivaram et al., and other applications owned by the assignee of the present application, including Herner, earler incorporated, and Hilali et al., US patent application No. 12/399,065, “Photovoltaic Cell Comprising an MIS-Type Tunnel Diode,” filed Mar. 6, 2009, and hereby incorporated by reference, describe embodiments in which the semiconductor donor body is affixed to a rigid or nearly rigid receiver element, such as semiconductor, glass, or metal. Following cleaving, the lamina remains affixed to the receiver element.

For a variety of reasons, it may be useful for the receiver element, to which the donor body is affixed before cleaving of the lamina, to be flexible. This is difficult to achieve, however, in that most flexible materials which could be used in production, such as rubber and most plastics, cannot tolerate high temperature, for example temperatures above about 300 to 400 degrees C. In general, completion of the photovoltaic cell following fabrication of the lamina requires temperatures at least this high.

In the present invention, a polymer that can tolerate high temperature is used as a receiver element. Polyimide, a polymer of imide monomers, readily tolerates relatively high temperature and has proven particularly advantageous for this purpose. Other temperature-tolerant polymers could be used as well.

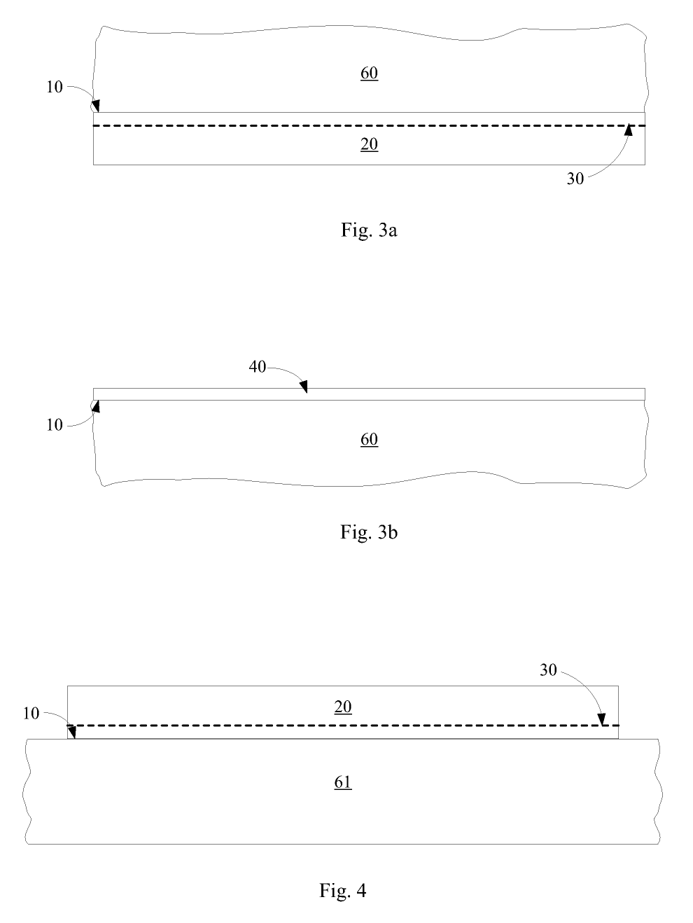

The polyimide material can be formed and adhered to the donor body in a variety of ways. Referring to FIG. 3a, a donor body 20, for example a donor wafer, has a cleave plane 30 previously defined, for example by ion implantation through first surface 10, as described earlier. Note that drawings are not to scale. Polyimide 60 in liquid form can be applied to first surface 10 of the silicon donor body by any suitable method; for example it may be spun on, sprayed on, or spread on. Liquid polyimide normally is then cured. Curing of polyimide body 60 may be preceded by a drying step, for example at about 130 to about 200 degrees C. This is followed by curing at, for example, about 350 to about 400 degrees C., though curing may be performed in other temperature ranges. In some embodiments, multiple applications of liquid may be used to form a thicker cured polyimide body 60. Turning to FIG. 3b, the heating step performed to cure the polyimide body 60 can be continued until cleaving of lamina 40 from the donor wafer is achieved. FIG. 3b shows the structure inverted, with cured polyimide body 60 on the bottom. At about 400 degrees C., for example, cleaving or exfoliation of lamina 40 can take place at 400 degrees C. in about six to eight hours. Depending on the dose and type of ions used during implantation, exfoliation can be faster or slower. In some embodiments, exfoliation can take place at temperatures up to about 600 degrees C., for example at 450, 500, or 550 degrees C. If desired, the structure could be cooled between the step of curing polyimide receiver element 60 and cleaving to form lamina 40, but in general it is economical to combine these steps.

Alternatively, turning to FIG. 4, first surface 10 of a donor body such as a donor wafer 20, having a previously defined cleave plane 30, can be placed adjacent to a pre-cured sheet of polyimide 61, which can be either fabricated or purchased. Heating the structure causes polyimide sheet 61 to soften and adhere to donor wafer 20. Light pressure, for example up to 1, 2, or 5 pounds, may optionally be applied as polyimide sheet 61 is adhered to donor wafer 20, though application of pressure is optional. Following additional heating, a lamina cleaves from donor wafer 20.

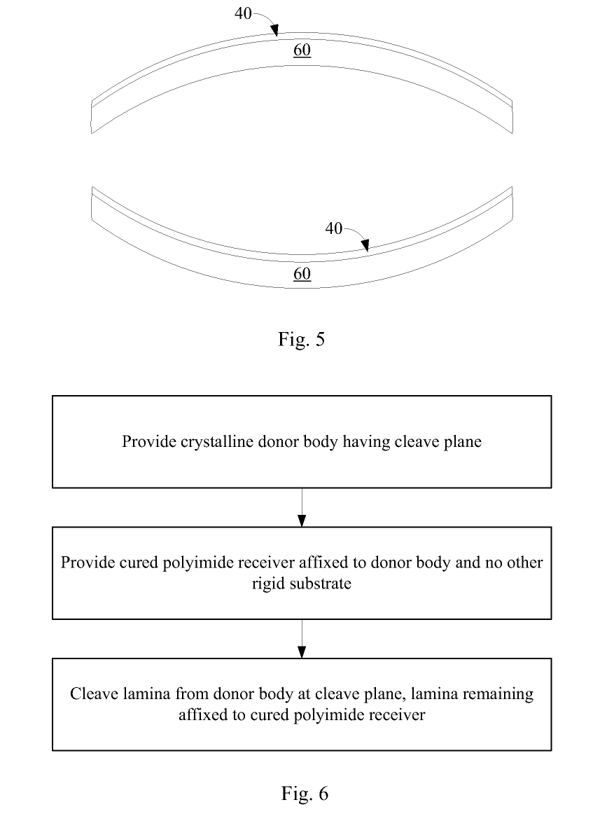

In the embodiments described, while the polyimide receiver element is being cured (if applied in liquid form) or adhered (in the form of a pre-cured sheet), the polyimide receiver element is adhered or affixed to the donor body only, and is not adhered or affixed to another rigid body. Referring to FIG. 5, following curing and/or adhesion, lamina 40 and polyimide receiver element 60 may be jointly flexed. Flexing is shown in both directions. In other embodiments, the polyimide receiver element may be adhered or affixed to another rigid body.

To summarize, FIG. 5 shows a flexible structure comprising: a substantially crystalline semiconductor lamina having a thickness less than about 50 microns; a polyimide substrate affixed to the semiconductor lamina, wherein zero, one, or more layers intervene between the semiconductor lamina and the polyimide substrate, wherein the substantially crystalline semiconductor lamina and the polyimide substrate can be jointly flexed and wherein the polyimide substrate is not affixed to another rigid substrate.

Such a structure is formed by a method comprising: providing a substantially crystalline semiconductor donor body having a cleave plane defined within; providing a cured polyimide receiver affixed to the donor body at a first surface of the donor body, wherein one or more layers have previously been formed on the first surface, and wherein the polyimide is affixed only to the semiconductor donor body and is not affixed to any other substrate; and cleaving a semiconductor lamina from the semiconductor donor body at the cleave plane, the semiconductor lamina remaining affixed to the cured polyimide receiver. This method is summarized in FIG. 6. A photovoltaic cell can be formed by providing a polyimide sheet and affixing a substantially crystalline semiconductor wafer to the polyimide sheet, the semiconductor wafer having a cleave plane defined within. This is followed by cleaving a semiconductor lamina from the wafer at the cleave plane, the semiconductor lamina remaining affixed to the polyimide sheet; and fabricating a photovoltaic cell, wherein the photovoltaic cell comprises the semiconductor lamina. The lamina may have a thickness more than about one micron, for example between about two or three microns and about five or six microns.

Using a flexible receiver element with a semiconductor lamina having a thickness of, for example, 50 microns or less has several advantages. A very thin lamina of semiconductor material such as silicon, for example having a thickness of about 50 microns or less, in some cases 10 microns, 5 microns or less, is substantially more flexible than a full wafer having a conventional thickness of 250 microns, 300 microns, or more. Thus, the polyimide receiver element and the semiconductor lamina can be jointly flexed. Clearly excessive flexing may damage the lamina, but a degree of flexing can be tolerated with minimal or no damage. This allows, for example, large sheets of polyimide receiver element with a plurality of exfoliated laminae adhered to be rolled into large rolls for easy transport. A polyimide receiver element is lightweight compared with, for example, a glass or metal receiver element. On installation, a polyimide-backed photovoltaic cell including a thin lamina could be installed on a non-planar surface such as a curved skylight or bay window.

Photovoltaic cells having some flexibility have been formed using amorphous silicon. Photovoltaic cells formed according to methods of the present invention are flexible and are substantially crystalline, including little or no amorphous material. Donor wafers, and thus laminae, may be monocrystalline, multicrystalline, or polycrystalline, for example. Photovoltaic cells formed of crystalline semiconductor material generally have better carrier mobility, and thus higher efficiency, than photovoltaic cells formed of amorphous semiconductor material.

For clarity, detailed examples of a photovoltaic assembly including a polyimide receiver element and a lamina having thickness between 0.2 and 100 microns, in which a photovoltaic assembly comprising a thin semiconductor lamina adhered to a polyimide receiver element, according to embodiments of the present invention, will be provided. For completeness, many materials, conditions, and steps will be described. It will be understood, however, that many of these details can be modified, augmented, or omitted while the results fall within the scope of the invention. In these embodiments, it is described to cleave a semiconductor lamina by implanting gas ions and exfoliating the lamina. Other methods of cleaving a lamina from a semiconductor wafer could also be employed in these embodiments.

### Example: Application and Cure of Liquid Polyimide

The process begins with a donor body of an appropriate semiconductor material. An appropriate donor body may be a monocrystalline silicon wafer of any practical thickness, for example from about 200 to about 1000 microns thick. In alternative embodiments, the donor wafer may be thicker; maximum thickness is limited only by practicalities of wafer handling. Alternatively, polycrystalline or multicrystalline silicon may be used, as may microcrystalline silicon, or wafers or ingots of other semiconductors materials, including germanium, silicon germanium, or III-V or II-VI semiconductor compounds such as GaAs, InP, etc. In this context the term multicrystalline typically refers to semiconductor material having grains that are on the order of a millimeter or larger in size, while polycrystalline semiconductor material has smaller grains, on the order of a thousand angstroms. The grains of microcrystalline semiconductor material are very small, for example 100 angstroms or so. Microcrystalline silicon, for example, may be fully crystalline or may include these microcrystals in an amorphous matrix. Multicrystalline or polycrystalline semiconductors are understood to be completely or substantially crystalline.

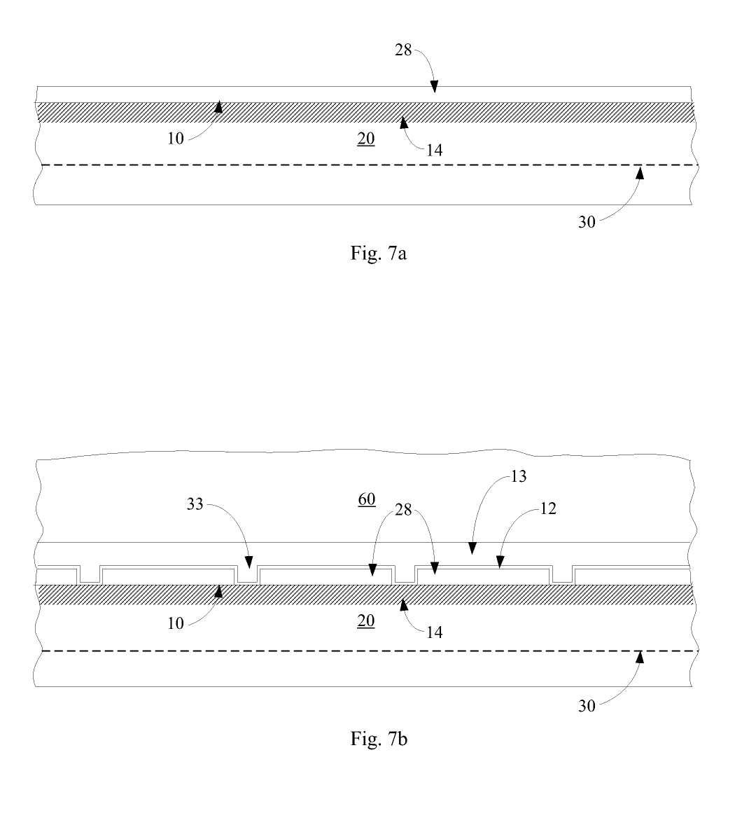

The process of forming monocrystalline silicon generally results in circular wafers, but the donor body can have other shapes as well. Cylindrical monocrystalline ingots are often machined to an octagonal cross section prior to cutting wafers. Multicrystalline wafers are often square. Square wafers have the advantage that, unlike circular or hexagonal wafers, they can be aligned edge-to-edge on a photovoltaic module with minimal unused gaps between them. The diameter or width of the wafer may be any standard or custom size. For simplicity this discussion will describe the use of a monocrystalline silicon wafer as the semiconductor donor body, but it will be understood that donor bodies of other types and materials can be used. Referring to FIG. 7a, donor wafer 20 is a monocrystalline silicon wafer which is lightly to moderately doped to a first conductivity type. The present example will describe a relatively lightly n-doped wafer 20 but it will be understood that in this and other embodiments the dopant types can be reversed. Wafer 20 may be doped to a concentration of between about 1×10¹⁵ and about 1×10¹⁸ dopant atoms/cm³, for example about 1×10¹⁷ dopant atoms/cm³. The fact that donor wafer 20 can be reused for some other purpose following exfoliation of one or more laminae makes the use of higher-quality silicon economical. Donor wafer 20 may be semiconductor-grade silicon, or even float-zone silicon, rather than solar-grade silicon, for example.

First surface 10 of donor wafer 20 may be substantially planar, or may have some preexisting texture. If desired, some texturing or roughening of first surface 10 may be performed, for example by wet etch or plasma treatment. Surface roughness may be random or may be periodic, as described in “Niggeman et al., “Trapping Light in Organic Plastic Solar Cells with Integrated Diffraction Gratings,” Proceedings of the 17^{th} European Photovoltaic Solar Energy Conference, Munich, Germany, 2001. Methods to create surface roughness are described in further detail in Petti, US patent application No. 12/130,241, “Asymmetric Surface Texturing For Use in a Photovoltaic Cell and Method of Making,” filed May 30, 2008; and in Herner, U.S. patent application Ser. No. 12/343,420, “Method to Texture a Lamina Surface Within a Photovoltaic Cell,” filed Dec. 23, 2008, both owned by the assignee of the present application and both hereby incorporated by reference.

First surface 10 may be heavily doped to some depth to the same conductivity type as wafer 20, forming heavily doped region 14; in this example, heavily doped region 14 is n-type. As wafer 20 has not yet been affixed to a receiver element, high temperatures can readily be tolerated at this stage of fabrication, and this doping step can be performed by any conventional method, including diffusion doping. Any conventional n-type dopant may be used, such as phosphorus or arsenic. Dopant concentration may be as desired, for example at least 1×10¹⁸ dopant atoms/cm³, for example between about 1×10¹⁸ and 1×10²¹ dopant atoms/cm³. Doping and texturing can be performed in any order, but since most texturing methods remove some thickness of silicon, it may be preferred to form heavily doped n-type region 14 following texturing.

In the present embodiment, dielectric 28 is formed on first surface 10. As will be seen, in the present example first surface 10 will be the back of the completed photovoltaic cell, and a reflective, conductive material is to be formed on the dielectric layer. The reflectivity of the conductive layer to be formed is enhanced if dielectric layer 28 is relatively thick. For example, if dielectric layer 28 is silicon dioxide, it may be between about 1000 and about 1500 angstroms thick, while if dielectric layer 28 is silicon nitride, it may be between about 700 and about 800 angstroms thick, for example about 750 angstroms. This layer may be grown or deposited by any suitable method. A grown oxide or nitride layer 28 passivates first surface 10 better than if this layer is deposited. In some embodiments, a first thickness of layer 28 may be grown, while the rest is deposited. In other embodiments, dielectric layer 28 may be omitted.

In the next step, ions, preferably hydrogen or a combination of hydrogen and helium, are implanted through dielectric layer 28 into wafer 20 to define cleave plane 30, as described earlier. The cost of this hydrogen or helium implant may reduced by methods described in Parrill et al., U.S. patent application Ser. No. 12/122,108, “Ion Implanter for Photovoltaic Cell Fabrication,” filed May 16, 2008, owned by the assignee of the present invention and hereby incorporated by reference. The overall depth of cleave plane 30 is determined by several factors, including implant energy. The depth of cleave plane 30 can be between about 0.2 and about 100 microns from first surface 10, for example between about 0.5 and about 20 or about 50 microns, for example between about 1 and about 10 microns or between about 1 or 2 microns and about 5 microns. Depth of cleave plane 30 may be about 3 or about 4 microns from first surface 10.

Turning to FIG. 7b, after implant, openings 33 are formed in dielectric 28 by any appropriate method, for example by laser scribing or screen printing. The size of openings 33 may be as desired, and will vary with dopant concentration, metal used for contacts, etc. In one embodiment, these openings may be about 40 microns square.

Next, a conductive layer or stack of conductive layers is deposited on dielectric layer 28, filling openings 33 and contacting heavily doped region 14 at first surface 10. A wide variety of materials or stacks of materials may be used, including tantalum, titanium, titanium nitride, aluminum, silver, copper, titanium, chromium, molybdenum, zirconium, vanadium, indium, cobalt, antimony, or tungsten, or alloys thereof. In the embodiment of FIG. 7b, this stack begins with a thin barrier layer 12 of a suitable material such as tantalum or titanium nitride. Thin barrier layer 12 may be between about 50 and about 700 angstroms, for example about 100 angstroms. Next is a thicker layer 13 of another material, preferably a material having a lower resistivity. In some examples layer 13 will be titanium, silver or aluminum. Layer 13 may be, for example, between about 100 angstroms and about 1 micron. In other embodiments, other conductive layers or stacks of conductive layers may be used instead.

To begin to form a polyimide receiver element, polyimide in liquid form is applied to the surface of donor wafer 20. Polyimide layer 60 can be applied by any of a variety of known methods. It may be spun on; in this case the thickness of layer 60 will vary with the volume applied and the spin speed. This layer may be sprayed on or applied by any other suitable method. A drying step is performed at, for example, about 120 to about 200 degrees C. for several minutes or hours. After drying, polyimide layer 60 is cured at a temperature between about 350 to about 400 degrees C. In some embodiments, the drying and curing steps may be combined. After curing, polyimide layer 60 may be, for example, between about 5 and about 30 microns thick. Multiple polyimide layers may be formed to create a thicker polyimide body, for example up to 100 microns thick or more; in this case curing time and temperature may be kept below exfoliation conditions until cure of the final layer. The process of applying polyimide in liquid form to the donor wafer, followed by drying and curing to form polyimide receiver element 60, is equivalent to the step of bonding to a rigid receiver, as described in Sivaram et al. and other incorporated applications.

Referring to FIG. 7c, depending on characteristics of the earlier ion implantation, including dose, uniformity, implant depth, and whether or not hydrogen was implanted alone or co-implanted with helium, exfoliation of lamina 40 can be achieved at about 400 degrees C. in about six to eight hours. FIG. 7c shows the structure inverted, with polyimide receiver element 60 on the bottom. Some polyimides can tolerate temperature up to about 650 degrees C. If such a polyimide is used, annealing to exfoliate lamina 40 may be performed at higher temperature, reducing anneal time. The steps of curing polyimide body 60 and exfoliating lamina 40 may be performed separately or may be combined. The thermal coefficient of expansion of polyimide is closely matched to that of silicon, reducing the risk of damage to either lamina 40 or polyimide receiver element 60 during processing. The thickness of lamina 40 is determined by the depth of the cleave plane defined earlier. In many embodiments, the thickness of lamina 40 is between about 1 and about 10 microns, for example between about 2 and about 5 microns.

Second surface 62 has been created by exfoliation. Some texturing or roughness may exist at second surface 62 upon exfoliation, which may be desirable to reduce reflection at this surface. If desired, an additional texturing step may be performed at second surface 62 by any of the methods described earlier. Such a texturing step may serve to remove damage at second surface 62. A specific damage-removal step may be performed, for example by etch or plasma treatment. Damage removal and texturing may be combined into a single step, or may be separate steps.

After removal of any native oxide that may have formed at second surface 62, in the present embodiment, a thin layer 72 of intrinsic amorphous silicon is optionally deposited on second surface 62. Layer 72 may be, for example, about 20 to 50 angstroms thick. In some embodiments, intrinsic amorphous layer 72 may be omitted. A layer 74 of heavily doped amorphous silicon is formed on layer 72, and may be, for example, about 300 angstroms thick. In general, the combined thickness of layers 72 and 74 will be between about 200 and about 500 angstroms, for example about 350 angstroms. Both amorphous silicon layers 72 and 74 are formed by any convention method, for example plasma enhanced chemical vapor deposition (PECVD). In this example, heavily doped amorphous layer 74 is doped p-type, opposite the conductivity type of lightly doped n-type lamina 40, and serves as the emitter of a photovoltaic cell, while heavily doped n-type region 14 provides electrical contact to the base region of the photovoltaic cell being formed, which is the lightly n-doped body of lamina 40.

In other embodiments, conductivity types of amorphous silicon layer 74, lamina 40, and heavily doped region 14 may be reversed. In still other embodiments, heavily doped region 14 will be opposite the conductivity type of the body of lamina 40, while heavily doped amorphous silicon layer 74 will be doped to the same conductivity type. In this case, heavily doped amorphous silicon layer 74 will provide electrical contact to the base region of the cell, while heavily doped region 14 will serve as the emitter of the cell.

A transparent conductive oxide (TCO) layer 110 is formed on heavily doped amorphous layer 74. Appropriate materials for TCO 110 include indium tin oxide, aluminum-doped zinc oxide, tin oxide, titanium oxide, etc.; this layer may be, for example, about 1000 angstroms thick, and serves as both a top electrode and an antireflective layer. In alternative embodiments, an additional antireflective layer (not shown) may be formed on top of TCO 110. Wiring 57 may be formed on TCO 110 by any suitable method.

FIG. 7c shows a completed photovoltaic assembly 80. Photovoltaic assembly 80 comprises lamina 40 and cured polyimide receiver element 60. In this embodiment, three layers, dielectric layer 28 and metal layers 12 and 13, intervene between lamina 40 and polyimide receiver element 60. In other embodiments, zero, one, two, or more layers may intervene between the lamina and the receiver element. Photovoltaic assembly 80 includes a photovoltaic cell, which in turn comprises lamina 40. Incident light, indicated by arrows, enters lamina 40 at second surface 62, and passes through lamina 40. Some or all light is reflected from metal layer 12, and reenters lamina 40 at first surface 10. Lamina 40 and polyimide receiver element 60 are both flexible and can be jointly flexed. Polyimide receiver element 60 is affixed to lamina 40 (with intervening dielectric layer 28 and metal layers 12 and 13) and at this stage is not affixed to any other rigid substrate. In some embodiments, photovoltaic assembly 80 may be affixed to a rigid substrate at some later time.

As noted earlier, donor wafer 20 (see FIG. 7a) can be reused, having additional laminae cleaved from it. When a lamina has been cleaved from a donor wafer, it leaves behind a rough surface. When a reused donor wafer and is to be bonded to a rigid substrate, as in Sivaram et al., Herner, and Hilali et al., all earlier incorporated, some degree of planarizing of the exfoliated surface of donor wafer 20 may be necessary before it can be successfully bonded to the rigid substrate. A polyimide receiver element, in contrast, will conform to an irregular surface, reducing or eliminating the need for such planarizing.

### Example: Preformed Polyimide Sheets

The previous embodiment described polyimide applied in liquid form to the surface of the donor body, then cured to form a polyimide receiver element. Polyimide can also be cured in the form of a sheet before being adhered to the donor body. Such polyimide sheets can be formed or may be purchased ready-made. Such sheets may have any suitable thickness, for example about 5 microns to about 500 microns or more.

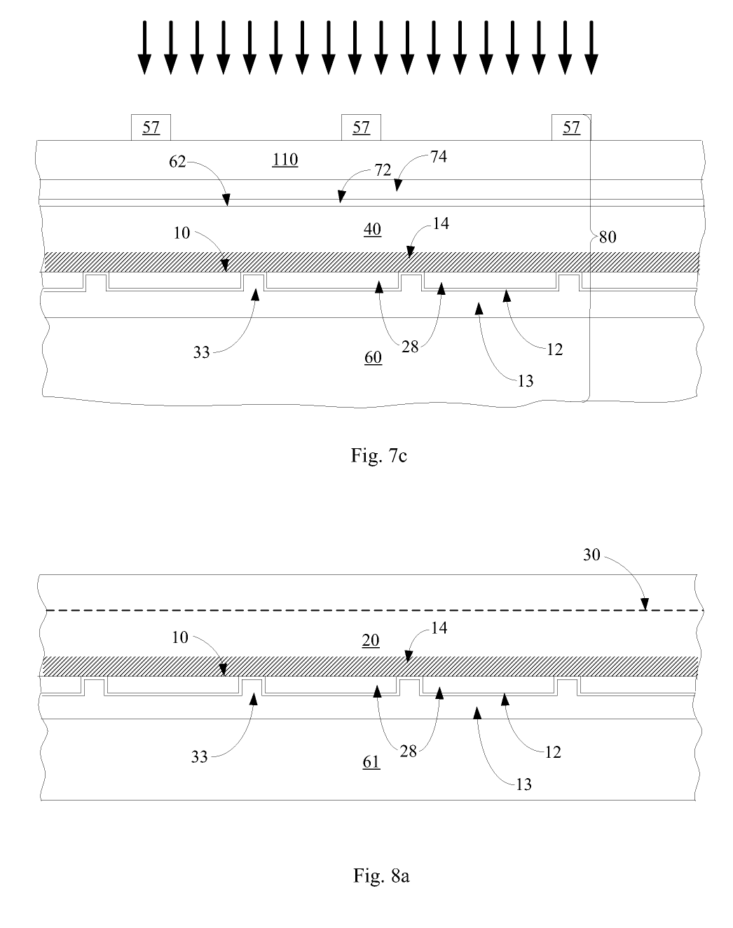

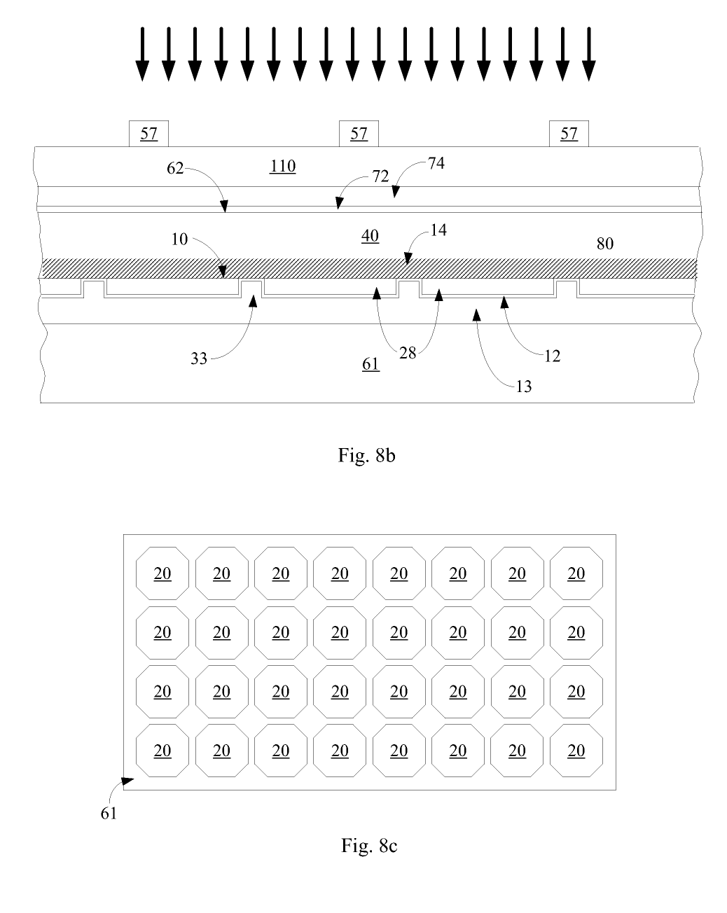

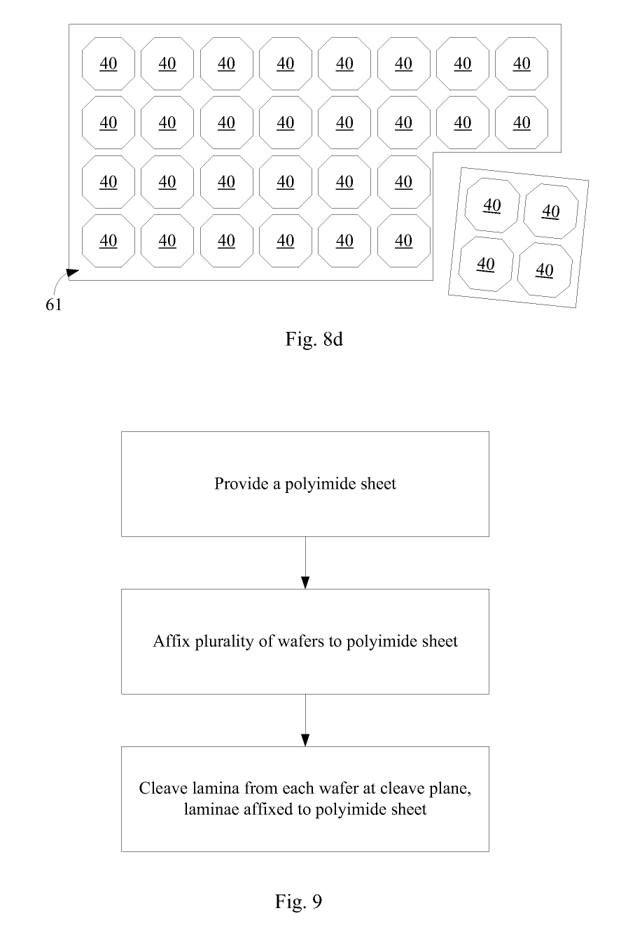

Turning to FIG. 8a, fabrication begins as in the prior embodiment: Heavily doped n-type region 14 is formed in donor wafer 40, and dielectric layer 28 deposited as before. Following ion implantation through first surface 10 to form cleave plane 30, openings 33 are formed in dielectric layer 33, and metal layers 12 and 13 are deposited by any suitable method.

Donor wafer 20 is placed adjacent to preformed polyimide sheet 61 at its first surface 10. Dielectric layer 28 and metal layers 12 and 13 intervene between first surface 10 and polyimide sheet 61. A heating step serves to soften polyimide sheet 61, causing it to adhere to donor wafer 20 and its associated layers. This heating step may be conducted between about 50 and 450 degrees C. for several minutes or hours. Pressure may be applied to help adhesion. Pressure may range from the weight of donor wafer 20 to one pound, five pounds, or more. The process of affixing donor wafer 20 to polyimide sheet 61 using heat, and possibly pressure, is equivalent to bonding. Turning to FIG. 8b, exfoliation of lamina 40 may be achieved during this heating step, or during a separate step.

Fabrication continues as in the prior embodiment. Following any cleaning or surface treatment of second surface 62, which was created by exfoliation, intrinsic amorphous silicon layer 72 and heavily doped amorphous silicon layer 74 are deposited, forming the emitter of the cell. Next comes deposition of TCO layer 110. Wiring 57 is formed on TCO layer 110. Lamina 40 and polyimide receiver element 61 are both flexible and can be jointly flexed. Polyimide receiver element 61 is affixed to lamina 40 (with intervening dielectric layer 28 and metal layers 12 and 13) and is not affixed to any other rigid substrate.

Referring to FIG. 8c, affixing multiple donor wafers 20 to the same polyimide sheet 61, for example in a reel-to-reel fabrication process, may speed processing and reduce cost. Following fabrication, polyimide sheet 61 with multiple laminae attached may be loosely rolled for easy transport. The laminae attached to a single polyimide sheet may be fabricated into photovoltaic cells, which are then attached electrically in series. The polyimide sheet and attached photovoltaic cells may serve as a photovoltaic module. Alternatively, referring to FIG. 8d, a section of sheet having one, two, or more laminae 40 adhered to it could be cut from the larger polyimide sheet 61 at any time after adhering. In the example shown in FIG. 8d, four laminae are adhered to the section cut from larger sheet 61. Such a section may be cut before or after exfoliation and subjected to separate fabrication steps; or after fabrication is complete, a section can be separated from polyimide sheet 61 to be transported or installed separately.

In some embodiments, the polyimide sheet may be in a laminate structure backed with another flexible material. For example, such a laminate structure may include polyimide and a flexible metal foil, such as steel, tin, aluminum, etc. In general the polyimide side of the structure will be adjacent to the lamina.

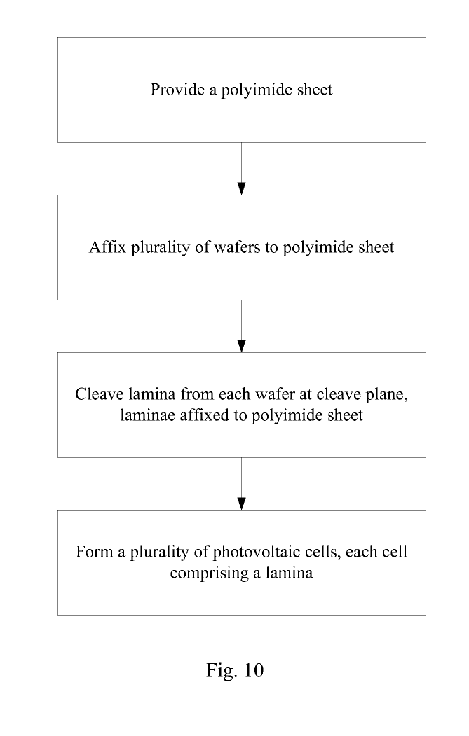

Summarizing, such a structure is formed by a method comprising: providing a polyimide substrate; affixing a plurality of substantially crystalline semiconductor wafers to the polyimide substrate, each semiconductor wafer having a cleave plane defined within; and cleaving a semiconductor lamina from each wafer of the plurality at the cleave plane, the semiconductor laminae remaining affixed to the polyimide substrate. The polyimide substrate may be a pre-formed polyimide sheet. This method to form a plurality of flexible structures is summarized in FIG. 9. A plurality of photovoltaic structures may be formed by fabricating a plurality of photovoltaic cells, wherein each photovoltaic cell comprises one of the semiconductor laminae. This method to form a plurality of photovoltaic cells is summarized in FIG. 10.

Electrical connection to back metal layers 12 and 13 may be made as described in Petti et al., U.S. patent application Ser. No. 12/407,064, “Method to Make Electrical Contact to a Bonded Face of a Photovoltaic Cell,” filed Mar. 19, 2009. Alternatively, such connection may be formed by way of a metal tab that protrudes past the edge of lamina 40 from these layers. In other embodiments, contact holes may be formed through the polyimide receiver element to contact metal layer 12.

Embodiments have been described in which polyimide in liquid form is applied to a donor body, as have other embodiments in which a donor body is adhered to a preformed cured sheet of polyimide. Clearly any other methods of forming a cured polyimide body adhered to a semiconductor donor body, which is not affixed to any other rigid structure, could be used as well, and are not intended to be excluded.

For completeness, detailed examples of fabrication of a specific type of photovoltaic cell adhered to a polyimide receiver element, with a particular details of doping, thickness, materials, method of forming electrical contact, etc., has been provided. It will be appreciated, however, that many types of photovoltaic cells, such as those described in the earlier incorporated applications, may be fabricated adhered to a polyimide receiver element according to embodiments of the present invention.

To summarize, FIGS. 6c and 7b show a flexible photovoltaic structure comprising: a substantially crystalline semiconductor lamina having a thickness less than about 50 microns; a polyimide substrate affixed to the semiconductor lamina, wherein zero, one, or more layers intervene between the semiconductor lamina and the polyimide substrate; and a photovoltaic cell, wherein the photovoltaic cell comprises the semiconductor lamina, wherein the polyimide substrate is not affixed to a rigid substrate. In some embodiments at least one conductive layer intervenes between the semiconductor lamina and the polyimide substrate. This conductive layer may be a metal layer comprising, for example, aluminum or silver. A dielectric layer intervenes between the semiconductor layer and the conductive layer.

Fabrication of a photovoltaic cell comprising a thin semiconductor lamina adhered to a flexible substrate has been described. Other types of devices may be fabricated in the semiconductor laminae instead, such as infrared detection devices, electronics, etc. An infrared detection device or electronic device will be fabricated which comprises at least a portion of the semiconductor lamina. A thinner lamina may be preferred when forming such devices, for example having a thickness of 0.5 microns or less.

A variety of embodiments has been provided for clarity and completeness. Clearly it is impractical to list all possible embodiments. Other embodiments of the invention will be apparent to one of ordinary skill in the art when informed by the present specification. Detailed methods of fabrication have been described herein, but any other methods that form the same structures can be used while the results fall within the scope of the invention.

The foregoing detailed description has described only a few of the many forms that this invention can take. For this reason, this detailed description is intended by way of illustration, and not by way of limitation. It is only the following claims, including all equivalents, which are intended to define the scope of this invention.

What is claimed is:

1. A method to form a plurality of flexible structures, the method comprising:
providing a polyimide substrate;
affixing a plurality of substantially crystalline semiconductor wafers to the polyimide substrate, each semiconductor wafer having a cleave plane defined within; and
cleaving a semiconductor lamina from each wafer of the plurality at the cleave plane, the semiconductor laminae remaining affixed to the polyimide substrate.

2. The method of claim 1 wherein the semiconductor wafers are monocrystalline silicon wafers.

3. The method of claim 1 wherein the semiconductor laminae have a thickness less than about 50 microns.

4. The method of claim 1 wherein each of the semiconductor laminae has a thickness between about 0.5 and about 20 microns.

5. The method of claim 1 further comprising fabricating electronic devices in the semiconductor laminae.

6. The method of claim 5 wherein the electronic devices comprise infrared detection devices.

7. The method of claim 1 wherein the cleave plane of each semiconductor wafer was defined by implanting hydrogen and/or helium ions into the semiconductor wafer before the affixing step.

8. A method to form a flexible structure, the method comprising
providing a substantially crystalline semiconductor donor body having a cleave plane defined within;
providing a cured polyimide receiver affixed to the donor body at a first surface of the donor body, wherein one or more layers have previously been formed on the first surface, and wherein the polyimide is affixed only to the semiconductor donor body and is not affixed to any other substrate; and
cleaving a semiconductor lamina from the semiconductor donor body at the cleave plane, the semiconductor lamina remaining affixed to the cured polyimide receiver.

9. The method of claim 8 wherein the step of providing the cured polyimide receiver comprises:
applying polyimide in liquid form to the first surface of the donor body, wherein zero, one, or more layers have previously been formed on the first surface; and
curing the polyimide to form the cured polyimide receiver.

10. The method of claim 8 wherein the semiconductor lamina has a thickness between about 0.2 microns and about 50 microns.

11. The method of claim 10 wherein the semiconductor lamina has a thickness between about 0.5 microns and about 20 microns.

12. The method of claim 8 further comprising fabricating a photovoltaic cell, the photovoltaic cell comprising the semiconductor lamina.

13. The method of claim 8 wherein the semiconductor donor body is a monocrystalline, multicrystalline, or polycrystalline silicon wafer.

14. The method of claim 8 further comprising fabricating electronic devices in the semiconductor lamina.

15. The method of claim 8 wherein the step of providing a cured polyimide receiver affixed to the donor body comprises:
providing a pre-cured polyimide sheet;
and affixing the donor body to the polyimide sheet.

16. A method to form a plurality of photovoltaic structures, the method comprising:
providing a polyimide substrate;
affixing a plurality of substantially crystalline semiconductor wafers to the polyimide substrate, each semiconductor wafer having a cleave plane defined within;
cleaving a semiconductor lamina from each wafer of the plurality at the cleave plane, the semiconductor laminae remaining affixed to the polyimide substrate; and
fabricating a plurality of photovoltaic cells, wherein each photovoltaic cell comprises one of the semiconductor laminae.

17. The method of claim 16 wherein the polyimide substrate is a pre-cured polyimide sheet.

18. The method of claim 16 wherein the semiconductor wafers are monocrystalline silicon wafers.

19. The method of claim 16 wherein the semiconductor laminae have a thickness between about 0.5 microns and about 20 microns.

20. The method of claim 16 wherein the cleave plane of each semiconductor wafer was defined by implanting hydrogen and/or helium ions into the semiconductor wafer before the affixing step.

21. The method of claim 16 wherein a conductive layer intervenes between at least one lamina and the polyimide substrate.

22. The method of claim 21 wherein the conductive layer comprises a metal layer.

23. The method of claim 22 wherein the metal layer comprises aluminum.

24. The method of claim 22 wherein the metal layer comprises silver.

25. The method of claim 21 wherein a dielectric layer intervenes between the conductive layer and the semiconductor lamina.

26. The method of claim 16 further comprising, before the affixing step, doping a first surface of at least one semiconductor wafer, wherein during the affixing step the lamina is affixed to the polyimide substrate at the first surface with zero, one, or more layers intervening between the first surface and the polyimide substrate.

27. A method to form a photovoltaic cell, the method comprising:
providing a polyimide sheet;
affixing a substantially crystalline semiconductor wafer to the polyimide sheet, the semiconductor wafer having a cleave plane defined within;
cleaving a semiconductor lamina from the wafer at the cleave plane, the semiconductor lamina remaining affixed to the polyimide sheet, the lamina having a thickness between about two and about six microns; and
fabricating a photovoltaic cell, wherein the photovoltaic cell comprises the semiconductor lamina.
